(19) United States
(12) Patent Application Publication
(10) Pub. No.: US 2008/0204025 A1
(43) Pub. Date: Aug. 28, 2008

(54) Tool and Method for Shimming a Magnet

(75) Inventors: Gregory Eymin-Balzano, Francheville (FR); Karen Hayes, Oxford Oxfordshire (GB); Raymond Hornsby, Witney Oxfordshire (GB); Andrew Wren, Oxford Oxfordshire (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney Oxfordshire (GB)

(21) Appl. No.: 11/579,768

(22) PCT Filed: Apr. 8, 2005
(86) PCT No.: PCT/EP2005/003711

§ 371 Date: Jan. 31, 2008

(30) Foreign Application Priority Data
May 14, 2004 (GB) 0410753.8

(51) Int. Cl. G01R 33/3873

(52) U.S. Cl. 324/320

(57) ABSTRACT

The invention provides tools and methods for shimming magnets such as MRI and NMR magnets, while at field. The invention provides safe methods for shimming at field. The invention particularly provides a tool (40) for withdrawing and inserting a shim tray (7) into slots (34) in a magnet (30), in the presence of a magnetic field. The tool comprises a channel (11, 12) for guiding a shim tray, alignment means (64, 74, 76, 6) for aligning the channel with a selected slot, a drive means (9) arranged to propel a shim tray along the channel; and a connector (96) arranged to detachably link the drive means to a shim tray.

In applications such as magnetic resonance imaging (MRI) or nuclear-magnetic resonance (NMR), a very strong, homogeneous magnetic field must be produced in an imaging region to allow effective imaging to take place. There are several ways to homogenise a magnetic field, but a common, repeatable and cost effective way is with the use of passive shims. Small pieces of sheet steel, iron, or other ferromagnetic material, known as shims, are inserted inside the bore of the magnet in question. The shims may be of varying thicknesses and are placed so as to distort the magnetic field in such a way that the homogeneity of the magnetic field in the imaging region is improved. The shims are typically placed within pockets in a shim tray, and the shim tray then held within the bore of the magnet. The arrangement of shims, shim pockets and shim trays is known as a shim set. The process of arranging the shims in this way is known as shimming. The size and material of the shims affects the level of homogeneity that can be achieved.

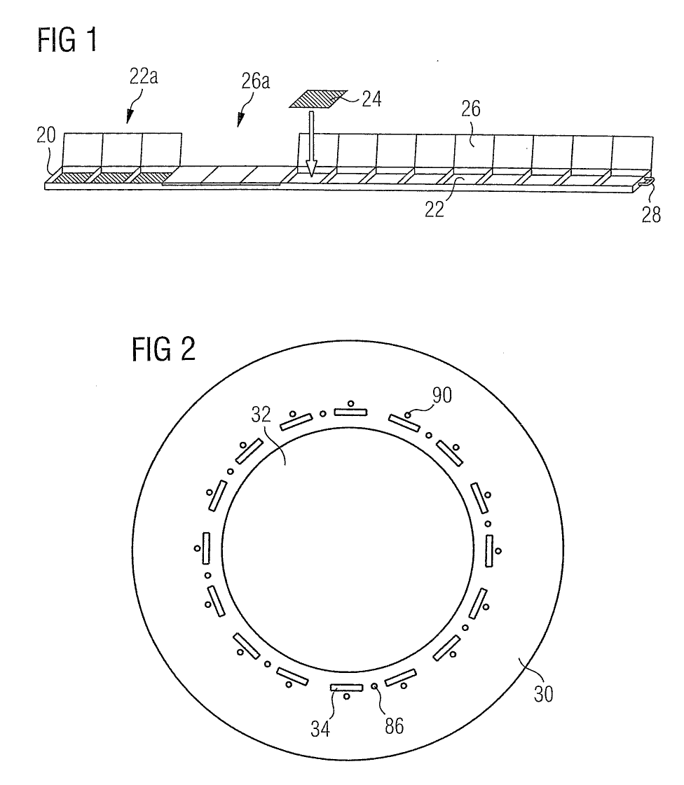

FIG. 1 shows, very schematically, a shim tray 20 of known type. A number of shim pockets 22 are provided along the length of the shim tray. Ferromagnetic shims 24 may be placed in the pockets 22. In FIG. 1, some of the shim pockets 22a are shown containing different quantities of shims. Each shim pocket may be provided with a lid 26. Some of the lids 26a are shown closed over the respective shim pockets.

FIG. 2 shows an end view of a gradient coil casing of a MRI or NMR system. The magnet gradient coil (not shown) is enclosed in a resin casing 30, around a central bore 32. The imaging region is located within the central bore. A very high, very homogeneous magnetic field must be produced within the imaging region, and the process of shimming is known to improve homogeneity. The resin casing 30 contains a number of shim tray slots 34, arranged around the inner periphery of the casing 30, between the coil and the central bore 32. Each one of these shim tray slots 34 is arranged to house a shim tray 20. By selecting a combination of a shim pocket 22 and a shim tray slot 34, shims may be placed at virtually any location around the periphery of the inner bore 32. In the illustrated example, sixteen shim tray slots 34 are provided, for shim trays each typically having fifteen shim pockets 22. In total, this provides 240 possible locations for shims. Other numbers of shim tray slots and numbers of shim pockets per tray may of course be used. Since the effects of the shims are interrelated and due to the number of variables involved, a computer simulation is typically used in order to decide how many shims should be placed in each pocket.

A handle 28 is schematically represented in FIG. 1, for use in pulling the shim tray out of the gradient coil.

A typical method for shimming a magnet, that is, placing the required number of shims in each shim pocket to produce the optimally homogeneous magnetic field in the imaging region, proceeds as follows.

The magnet is “ramped up”, which signifies being brought into operation at its full field strength. The magnet is then said to be “at field”. The magnet is usually maintained in this state for at least thirty minutes to allow stabilisation of the magnet. A measurement, “plot”, of field strength and homogeneity within the imaging region is then taken. A suitable computer-based model calculates a recommended arrangement of shims in the shim pockets 22 in the shim trays 20 in the shim tray slots 34. The magnet is then “ramped down”, which essentially signifies turning the magnet off in a safe and controlled manner. The recommended shims are placed in the appropriate shim pockets 22 of shim trays 20 which are placed in the appropriate shim tray slots 34. The magnet is then ramped up again, and the process repeated. Typically, three cycles, or iterations, of ramping up, plotting, ramping down and arranging shims in the shim trays are necessary to obtain the required degree of homogeneity. The required degree of homogeneity may be of the order of one part per million.

This is a time consuming exercise given the cryogenic and magnetic stabilisation requirements. On average, a time of two hours is required for one ramp cycle between the completion of shim loading and being able to plot again. Another disadvantage of repeated ramp cycles is that, when the magnet is ramped up and ramped down, its properties may change slightly, giving rise to a shift in the homogeneity of the magnetic field. Although the computer model may calculate an optimal shimming to treat the inhomogeneities measured during plotting, the magnet may change between ramping cycles, so that the calculated shim arrangement no longer provides optimal shimming. A further disadvantage in repeatedly ramping a cryogenic magnet is that each ramp cycle consumes a significant quantity of liquid cryogen.

The correct procedure for shimming involves ramping the magnet up and down, plotting the magnetic field with the magnet in operation, “at field”, and arranging the shims with the magnet turned off. Due to the length of time required to perform these operations, there is a temptation to shorten the correct procedure by pulling shim trays 20 out of the shim tray slot 34, or inserting them, by hand with the magnet at field. While such operation could never be considered safe, there are various factors affecting the level of risk in doing this. For example a 1 Tesla magnet with small shim iron pockets presents a fairly low risk to a person pulling the trays in and out at field. On the other hand, larger shim iron pockets on a 1.5 Tesla magnet present an enormous safety risk to someone wishing to pull the trays out of the magnet at field. In larger magnets, forces of around 4 kN may be exerted on the shim trays, meaning that it is impossible to remove them by hand.

The present invention accordingly aims to provide tools and methods for shimming a magnet such as an NMR or MRI magnet while at field. The present invention addresses this aim by providing apparatus and methods as defined in the appended claims.

The present invention allows a magnet to be shimmed at field, avoiding the time-consuming need for repeated ramping down and ramping up of magnets during shimming. The target time required for shimming a magnet using the apparatus and methods of the present invention is less than a day, more particularly, less than ten hours so that shimming may be completed within a single working day. This compares vary favourably with the two days previously required for shimming a magnet using ramping cycles. The present invention also avoids the shifts in homogeneity which may take place as a result of ramping cycles, by avoiding the need for ramping down and ramping up.

The above, and further, objects, characteristics and advantages of the present invention will become more apparent by reference to the following description of certain embodiments, with reference to the accompanying drawings, wherein:

FIG. 1 shows a schematic drawing of a shim tray and shims;

FIG. 2 shows an end view of a magnet gradient coil;

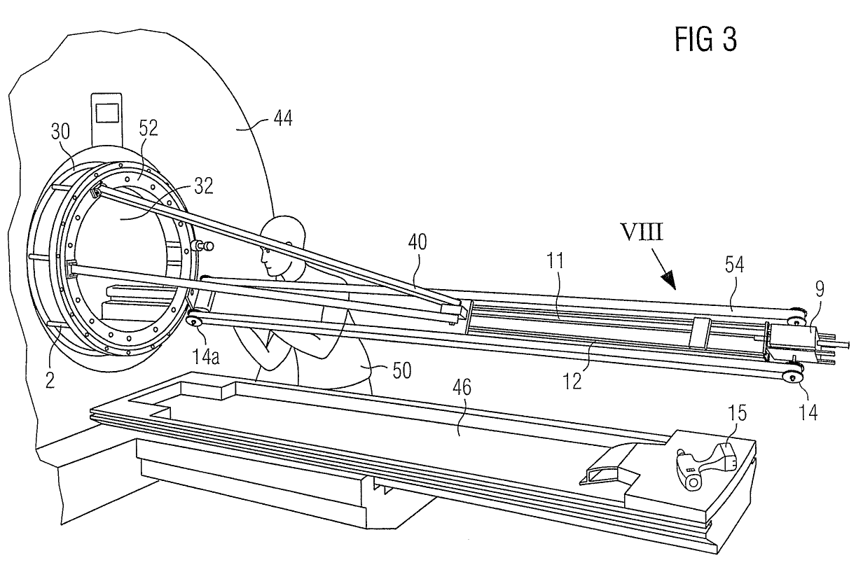

FIG. 3 shows a perspective view of the apparatus of the present invention in use;

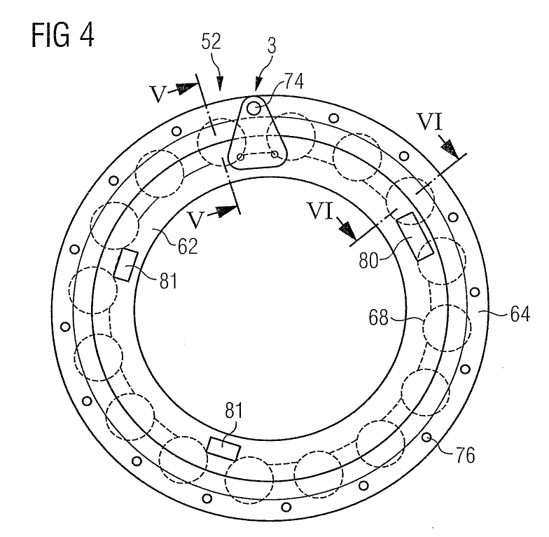

FIG. 4 shows an axial view of a first sub-assembly of the tool of the present invention;

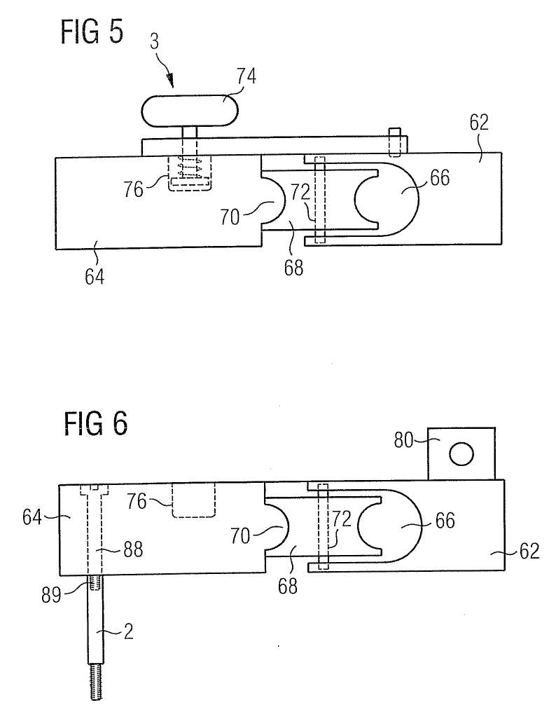

FIGS. 5-6 show certain features of the sub-assembly of FIG. 4, in cross-section;

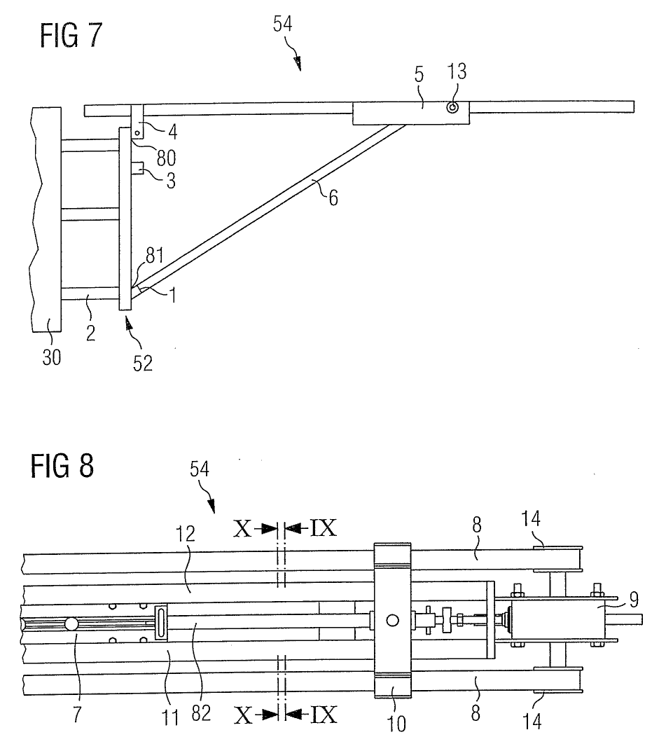

FIG. 7 shows a schematic elevation view of the apparatus of the present invention in use;

FIG. 8 shows a schematic plan view of a second sub-assembly of the apparatus of the present invention in use;

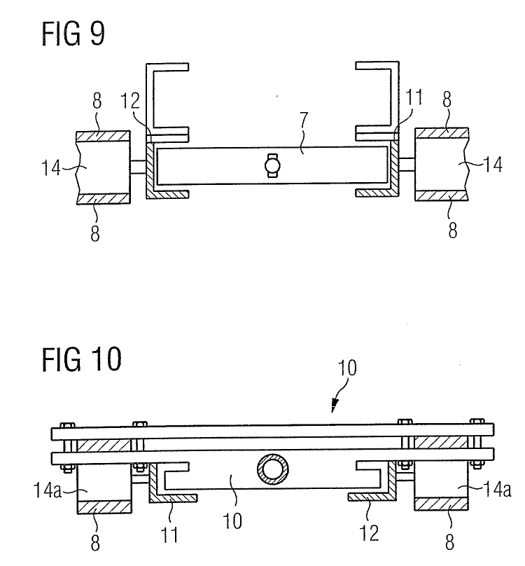

FIGS. 9-10 show certain features of the sub-assembly of FIG. 8, in cross-section;

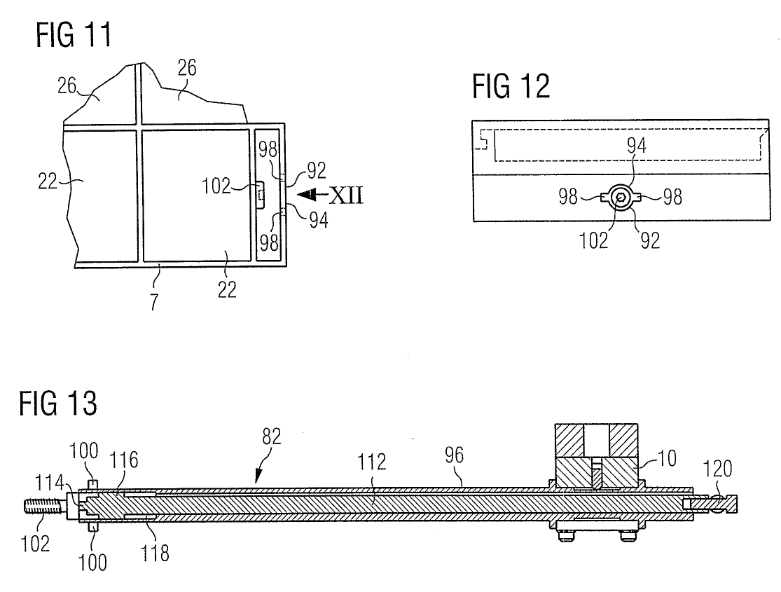

FIGS. 11-12 show plan and end views of a shim tray adapted for use with the tool of the invention; and

FIG. 13 shows a tool according to another aspect of the present invention.

The shim-at-field tool provided by the present invention allows shim trays to be inserted into, and removed from, the shim tray slots of the magnet gradient coil effectively, safely and rapidly, with the magnet at field. The invention also provides a new method of shimming a magnet at field, in which method there is no requirement for ramping the magnet up or down. A greater homogeneity can be achieved in the resultant field, since the field is not varied by ramp cycles, and much time may be saved in the shimming process.

In an embodiment of the present invention, a shim-at-field tool is provided for shimming the new OR105 product that is a 1.5 Tesla active shielded magnet for the Magnetom Avanto whole body MRI scanner manufactured by Siemens AG. While this embodiment will be specifically described in the following description, a tool according to the present invention may be used with many other types of magnet system.

FIG. 3 shows a tool 40 according to an embodiment of the present invention, in operation. It is mounted to the gradient coil housing 30 of an MRI magnet 44. In use, a patient is placed on an elevating patient bed 46, and is raised and slid into position within the bore 32 of the gradient coil when imaging is to take place. As will be described further below, the patient bed 46 may be employed to assist the mounting and removal of the tool 40. The tool and method of the present invention allows a single operator 50 to remove and insert shims in safety, even with the magnet at field.

In the illustrated embodiment, the tool is composed of two main sub-assemblies and some additional parts. The first sub-assembly 52 is a rotating and indexing mechanism. It is attached to the side of the gradient coil and allows the tool to rotate and index on each of a number of positions, each position corresponding to the location of a shim tray slot 34. In the illustrated embodiment, sixteen positions are provided, each corresponding to a shim tray slot. The second sub-assembly 54 is the main part of tool. It includes support guides 11, 12 for the shim tray and an extraction/insertion mechanism, to be described.

FIG. 4 shows a schematic axial view of the first sub-assembly 52. FIGS. 5 and 6 show cross-sections of the sub-assembly 52 along the lines V-V, VI-VI, respectively. The first sub-assembly 52 provides a means for mounting the shim-at-field tool to the magnet, and also provides a rotation mechanism which allows the tool to be moved smoothly to correctly and accurately align with each of the shim tray slots 34 in the gradient coil casing 30. The first sub-assembly also provides support to the shim-at-field tool and keeps it perpendicular to the gradient coil. The rotation mechanism consists of two rings, one internal 62 and one external 64. The external ring 64 is mechanically mounted onto the gradient coil by way of spacers 2 (FIG. 6). These spacers may be made of brass. The external ring 64 remains in a fixed position throughout the shimming process. The internal ring 62 consists of a channel 66 (FIGS. 5,6) housing wheels 68 which are in rolling contact with a mating radiused surface 70 on the external ring 64. Each wheel is mounted on axis 72 to the internal ring 62, so that the internal ring may rotate within the external ring, but still be resistant to axial and radial forces generated by the magnet. In alternative embodiments, the mating surface may be convex or concave, with the contacting surfaces of wheels 68 being complimentarily concave or convex.

Incorporated into the internal ring 62 is an indexing device 3 which ensures that the shim-at-field-tool is exactly aligned with each pocket when in use. The indexing device is more clearly shown in FIG. 5. A spring-loaded plunger 74 is biased towards the external ring 64, such that the plunger 74 may run along the external ring until it locates in one of a plurality of indexing holes 76, placed at predetermined positions, each positioned to align the shim-at-field tool of the invention with a corresponding shim tray slot. This mechanism prevents the tool from total free movement, and in doing so acts as a safety device, avoiding the tool swivelling unnecessarily, and requiring a positive operator action to disengage the tool from each shim tray slot. The indexing device 3, mounted to the internal ring, may be used as a handle to assist the operator in rotating the internal ring.

As shown in FIGS. 4 and 6, a main mounting point 80 is provided on the internal ring 62. As illustrated in FIG. 7, the second sub-assembly 54 is attached to the mounting point 80, for example by a bolt or pin, held in place by any suitable means. Further mounting points 81 are also provided on the internal ring 62, in a region generally opposite the location of the main mounting point 80. As also shown in FIG. 7, support struts 6 are attached to further mounting points 81, to hold the second sub-assembly securely in place. The support struts 6 may attach to the further mounting points by way of bolts, pins or any other suitable fixings. The internal and external rings 62, 64 may be made of aluminium, as may the mounting points 80, 81, the axles 72 and the sprung pin 74. The wheels 68 may typically be of PTFE, ABS, nylon or other suitable material.

FIG. 7 shows a schematic side view of the first and second sub-assemblies 52, 54, mounted together and on a gradient coil. As shown, a mounting portion 4 of the second sub-assembly 54 attaches to the main mounting point 80 of the first sub-assembly. A mounting portion 1 of each support strut 6 attaches to each further mounting point 81.

FIG. 8 shows a view of the second sub-assembly in the general direction VIII shown in FIG. 3. A shim tray 7 is shown. This shim tray has been adapted for use with the tool of the present invention as will be described in more detail below.

The mechanism to insert and extract the shim trays 7 in and out of the gradient coil includes a channel in which the shim tray travels. This channel is defined by support channels 11, 12 and prevents movement of the shim tray in a direction radial to the bore 32 of the magnet.

The shim tray 7 is placed in a channel defined by two channel sections 11, 12. The carrier 10 is clamped or otherwise fixed to each of two drive belts 8. The channel sections 11, 12 may be open-topped L-shaped sections in the region furthest from the magnet, to allow shim trays to be loaded. Nearer the magnet, the channel sections may be closed-topped C-sections, to prevent the shim tray from moving in any direction perpendicular to the channel, and to hold the shim tray lids 26 in the closed position.

A mechanical link 82 fixes to an end of the shim tray and allows the shim tray to be pushed and pulled by a carrier 10. The movement of carrier 10 and so also the shim tray 7 is achieved by using two drive belts 8 mounted on pulleys 14 at each end of the tool. A drive source 9 which is positioned at the end of the tool furthest from the gradient coil drives the adjacent pulleys. The drive source 9 may comprise a 10:1 gearbox 9 powered by an electric drill or electric screwdriver 15. An electric screwdriver has been found to be appropriate in this application, since it provides an appropriate torque and drive speed, is lightweight and simple to use while being inexpensive, and simple to operate in forward and reverse directions. Reversing the direction of the drive reverses the rotation of the pulleys 14 and so also reverses the direction of travel of the shim tray along the channel. The gearbox may be selected as required to provide the required torque and speed of rotation to the pulleys 14.

Although described above with reference to pulleys 14 and belts 8, other embodiments may employ equivalent means such as a worm gear with wheel leadscrew, or a cable, or a pulley with a rope. The drive source may be permanently attached to the tool. Alternatively, a conventional manual handle, accompanied by suitable mechanical drive mechanism, may be used as the drive source.

The carrier 10 is clamped onto both of the belts 8 either side of the support channels 11, 12. This ensures that the shim tray is transferred smoothly, without twisting as it travels along the length of the channel into or out of the shim tray slot 34.

FIGS. 9 and 10 schematically show views taken along the lines IX-IX and X-X respectively in FIG. 8. As shown in FIG. 9, further pulleys 14a are provided to carry the drive belts 8 at the distant end of the tool.

The shim-at-field tool preferably has two set positions: one being the shimming position, when the tool is in contact with the face of the gradient coil; the other being when the tool is away from the face of the gradient coil to allow for rotation. This second position may also be defined so as to provide clearance past a body coil, which may protrude at the base of the magnet, in some magnet types. These two positions are set by a second spring-loaded plunger 13 (FIG. 7) which locks into indexing holes defined along the support channel 11, 12. Further support and restraining means are also provided at the main mounting 4 to hold the tool in place.

The attachment of the shim tray to the carrier is preferably by way of a bayonet tool arrangement on the end of the mechanical link 82. According to an aspect of the present invention, the shim-at-field tool may provide an integrated screwdriver incorporated into the mechanical link 82, to allow the simple and safe securing of the shim trays to the gradient coil and to provide a complete quick release assembly. The shim tray 7 can be secured into the gradient coil from a safe distance with ease, and no other tools are required.

### Assembly of the Tool to the Magnet

When shimming of a magnet is to take place, the spacers 2—typically of brass but possibly of aluminium or a plastic material—are attached to the housing 30 of the gradient coil. This is typically achieved by screwing a threaded end portion of each spacer 2 into a corresponding threaded hole 86 (FIG. 2) provided in the housing 30 of the gradient coil. The first sub-assembly 52 is then attached to the spacers 2, for example by screwing threaded bolts 88 (FIG. 6) into corresponding threaded holes 89 in the tops of spacers 2. The inner ring 62 is then preferably rotated until the locating pin 74 latches into one of the corresponding holes 76 (FIG. 5), to hold the inner ring in position for aligning the tool with one of the shim tray slots 34.

The second sub-assembly 54 may be placed on the patient bed 46, which may be raised up, so that the second sub-assembly 54 may be raised to the appropriate height, and attached to the first sub assembly, as shown in FIG. 7. Mounting point 4 of the second sub-assembly may be attached to the main mounting point 80 (FIG. 4) of the first sub-assembly. The mounting points 1 of the support struts 6 may then be attached to the further mounting points 81 of the first sub-assembly. The central channel 11, 12 is then held in the horizontal position by support arms 6 which are fixed to the internal ring 62. This gives the whole tool a triangular formation, which allows the forces to be equally distributed around the internal ring 62.

### Insertion of a Shim Tray

To insert a shim tray 7 using the shim-at-field tool of the present invention, the shim tray is first loaded with shims in the required manner, typically being as recommended by a computer based model, as discussed above. The tray is then placed into the channel 11, 12 at the end furthest from the magnet. At this end, the channel parts 11, 12 are L-shaped as shown in FIG. 10. The mechanical link 82 is then attached into the corresponding receiving arrangement in the end of shim tray 7. The driver 9 is then operated, for example by engaging an electric drill/screwdriver with a gearbox. The drill/screwdriver and the gearbox will cause pulleys 14, drive belts 8 and so also carrier 10 and shim tray 7 to advance along the channel 11, 12 towards the magnet. The shim tray will now pass through the C-shaped channel sections shown in FIG. 9, which prevent movement of the shim tray in any direction perpendicular to the axis of the gradient coil, and also prevent the lids of the shim pockets from opening. Both of these possibilities become more likely as a loaded shim tray moves closer to a magnet at field. The drive 9 and the pulleys 14 may be arranged such that the tray progresses along the channel at a speed of approximately 0.25 metres per second. When the shim tray is fully inserted into the gradient coil, a suitable mechanical stop will be encountered, and the shim tray will stop moving. A clutch mechanism of some sort is preferably built into the drive 9, so that no mechanical shock is caused to the shim-at-field tool by the shim tray meeting the mechanical stop. Alternatively, an electrical switch may be provided in the channel 11, 12 to detect the arrival of the carrier 10 at a position corresponding to full insertion of the shim tray. A signal may be sent by the switch to indicate that the tray is fully inserted. The signal may alert the operator 50 to stop the drive 9, or the signal may be connected to automatically stop the drive.

Once the shim tray is in place, it must be securely retained there to prevent the high magnetic field of the magnet from forcing the shim tray out of its slot. Typically, threaded holes 90 (FIG. 2) may be provided, one in proximity to each shim tray slot. A screw may be provided in the end of shim tray 7 for attachment into the corresponding threaded hole 90.

FIG. 11 shows a plan view of a shim tray 7 adapted for use with the present invention. FIG. 12 shows and end view of the shim tray of FIG. 11, in the general direction shown by arrow XII. FIG. 13 shows an axial cross-section of the mechanical link 82. These three drawings will be discussed together. In the end of the shim tray 7, a bayonet type socket 92 is provided. It has a central hole 94 allowing the passage of the body 96 of the mechanical link 82, and bayonet slots 98 allowing the passage of bayonet lugs 100, when the body 96 of the mechanical link 82 is correctly aligned. To engage the mechanical link 82 with the shim tray, the body 96 is rotated so that the bayonet lugs 100 align with the bayonet slots 98. The body 96 is then pushed towards the shim tray 7 so that the lugs 100 pass through the slots 98. The body 96 is then rotated to an engaged position so that the shim tray may be pushed by the body 96, or pulled by the lugs 100. An indexing mechanism may be provided in carrier 10 to hold the body 96 in the aligned and engaged positions.

A fixing screw 102 is preferably provided in the end of the shim tray. The fixing screw is provided to allow the shim tray 7 to be mechanically attached to the gradient coil housing 30 at the threaded inserts 90. Once a shim tray 7 is located in the corresponding shim tray slot, the tray must be attached to the gradient coil housing before the mechanical link 82 is detached. Since the magnet is to be shimmed at field, any shim tray 7 which is not securely mechanically held in place may be violently expelled from the magnet. There is a difficulty in ensuring that the tray is securely fastened before withdrawal of the mechanical link 82, since the presence of mechanical link 82 obstructs normal access to the retaining screw 102. According to an aspect of the present invention, this difficulty is overcome by arranging the retaining screw 102 to be coaxial with the hole 94, and providing a screwdriver 112 running through the centre of a hollow mechanical link 82. As illustrated in FIG. 13, the screwdriver has a drive bit 114 appropriate to drive the retaining screw 102. The screwdriver is preferably retractable, and is shown in a retracted position in FIG. 13. The profile of the screwdriver is preferably stepped 116, with a complementary step 118 being provided in the inner profile of the body 96 to prevent the screwdriver being forced out of the body 96.

In use, the body 96 will engage with the shim tray as discussed, and will propel the shim tray into the shim tray slot as described. Once the shim tray is in place, the operator will advance the screwdriver to engage its drive bit 114 with the retaining screw 102. The handle 120 of the screwdriver may then be turned to drive the screw into the threaded insert 90 in the gradient coil casing 30. The handle 120 may be arranged so that is can be driven by an electric drill/screwdriver, for example the same drill/screwdriver used in drive 9. When a shim tray is to be removed, the body 96 will first engage with the shim tray by way of its bayonet mechanism 100, 98. The operator will then engage the screwdriver drive bit 114 with the retaining screw 102, and operate the screwdriver to remove the retaining screw. The shim tray 7 is then held by the mechanical link 82, and may be removed as will be described.

### Removal of a Shim Tray

Removal of the shim tray is essentially the reverse of the insertion operation described. With the help of the shim-at-field tool of the present invention, the operator 50 can extract a shim tray with little effort and safely, even with the magnet at field.

Firstly, the mechanical link 82 must engage with the shim tray 7. This may involve operating the drive 9 to displace the carrier 10 sufficiently in the direction of the gradient coil for the mechanical link 82 to engage. Once engaged, the shim tray should be released from the gradient coil, such as by use of integrated screwdriver 112. The shim tray 7 is then free to move under the control of the shim-at-field tool. The drive 9 is then operated in a reverse direction, and the shim tray is removed from the shim tray slot of the gradient coil safely, even with the magnet at field. The mechanical link 82 prevents the shim tray from moving along the channel other than as directed by the carrier 10. The C-shaped channel sections 11, 12, prevent the shim tray from moving in any other direction.

The drive 9 is operated until the shim tray reaches the end of the channel distant from the magnet. Here, the channel sections 11, 12 are L-shaped, enabling the shim tray to be removed as required to enable the arrangement of shims to be changed.

A typical shimming operation will accordingly involve an initial plot of the magnetic field within the imaging volume, followed by an initial arrangement of shims in the shim trays according to a recommendation supplied by a computer based model based on the plot. The shim trays may then each be inserted into the respective shim tray slots according to the method described above. The magnet may remain at field throughout this process. A second plot may then be taken, and the computer based model will make a revised recommendation for the placement of shims. The shim trays may then be removed as required, as described above. Their contents may then be adjusted as required, and the shim tray returned to the corresponding shim tray pocket. The magnet may remain at field throughout this process. A third plot may then be taken, and the computer based model may make a revised recommendation for the placement of shims. If necessary, the process of removing shim trays, adjusting their contents and returning the shim tray to the corresponding shim tray pocket may also be repeated a third, or further, time. The magnet may remain at field throughout this process.

To allow for ease of transportation and storage, the shim-at-field tool of the present invention is preferably arranged such that it is able to fold. For example, support struts 6 may fold onto the first sub-assembly 52, or may fold onto the channels 11, 12 of the second sub-assembly 54. The channel supports 11, 12 themselves may fold in half, or into smaller sections. The channel supports may disassemble into sections. In one embodiment, the shim-at-field tool has been arranged to fold, and can be stored and transported within a typically sized suitcase. This is particularly advantageous for service engineers who may need to travel between sites to perform shimming operations in-situ. The suitcase sized shim-at-field tool may be easily carried by car, rail or air.

The shim-at-field tool of the present invention allows the shimming operation time to be performed in less than one day instead of the two days which have hitherto been necessary to shim an MRI or NMR magnet system, such as a Magnetom Avanto type system as made by Siemens AG. It is a one-man operation and the tool can be folded up in practical size for shipping. The process requires little effort from the operator. A novel shim tray design has been produced to interface with the quick release mechanism on the tool.

The features of securing the tray into a channel guide, which also serves to hold the pocket caps on and a mechanical pulling mechanism are believed to be novel. The size, strength and structure of the tool of the present invention is optimised so that the tool is considered transportable and yet strong enough to withstand the forces it operates with.

1. A tool for withdrawing and inserting a shim tray into slots in a magnet, in the presence of a magnetic field, comprising:
a channel for guiding a shim tray, the channel having a proximal end for location adjacent to the magnet, and a distal end for receiving and delivering shim trays;
alignment means for aligning the proximal end of the channel with a selected slot,
a drive means arranged to propel a shim tray along the channel; and
a connector arranged to detachably link the drive means to a shim tray.

2. A tool according to claim 1, further comprising a rotary indexing means joined between the magnet and the proximal end of the channel for aligning the channel with each slot in turn, selected from a plurality of available slots arranged in a circular formation around the magnet.

3. A tool according to claim 2, wherein the rotary indexing means comprises two concentric rings arranged for relative rotary motion, and wherein a first ring is arranged for rigid mounting on the magnet, while the second ring is arranged to receive the channel rigidly mounted thereto.

4. A tool according to claim 3, wherein the second ring carries a first mounting point for attachment to the proximal end of the channel, and at least one further mounting point for attachment to a first end of a corresponding at least one support strut, a second end of the or each strut being arranged for attachment to the channel, whereby a mechanically secure mounting of the channel to the second ring may be effected.

5. A tool according to claim 1, wherein the connector is attached to a carrier, said carrier being firmly attached to a drive belt, said drive belt being arranged to be driven by the drive means to propel the carrier and the connector along the channel.

6. A tool for attaching a shim tray to a magnet, said magnet including shim tray slots and a corresponding attachment point for receiving a retaining means, the tool comprising:
a hollow body carrying an engagement means for engaging a complimentary feature on a shim tray; and
a concentric attachment tool substantially located within the hollow body, arranged to engage and operate an attachment means located on the shim tray.

7. A tool according to claim 6, wherein the attachment point is a threaded insert; the retaining means is a screw, and the attachment tool is a screwdriver.

8. A tool according to claim 6, wherein the engagement means and the complementary feature together comprise a bayonet mechanism.

9. (canceled)

10. A method of inserting a shim tray into a magnet, comprising the steps of:
providing a channel having a proximal end located adjacent to the magnet and a distal end for receiving and delivering shim trays;
aligning the proximal end with a shim tray slot in a magnet;
placing a shim tray in the channel at the distal end;
connecting the shim tray to a drive means; and
propelling a shim tray along the channel and into a shim tray slot using the drive means.

11. A method of removing a shim tray from a magnet, comprising the steps of:
providing a channel having a proximal end located adjacent to the magnet and a distal end for receiving and delivering shim trays;
aligning the proximal end with a shim tray in a shim tray slot in a magnet;
connecting a shim tray to a drive means;
propelling a shim tray along the channel to the distal end using the drive means; and
removing a shim tray from the channel at the distal end.

12.-16. (canceled)

17. A tool for attaching a shim tray to a magnet, said magnet including shim tray slots and a corresponding attachment point for receiving a retaining means, the tool comprising:
a hollow body carrying an engagement means for engaging a complimentary feature on a shim tray; and
a concentric attachment tool substantially located within the hollow body, arranged to rotate within the hollow body, thereby to engage and operate an attachment means located on the shim tray.

18. A tool according to claim 17, wherein the attachment point is a threaded insert; the retaining means is a screw, and the attachment tool is a screwdriver.

19. A tool according to claim 17, wherein the engagement means and the complementary feature together comprise a bayonet mechanism.

20. A withdrawal tool for withdrawing and inserting a shim tray into slots in a magnet, in the presence of a magnetic field, comprising:
a channel for guiding a shim tray, the channel having a proximal end for location adjacent to the magnet, and a distal end for receiving and delivering shim trays;
alignment means for aligning the proximal end of the channel with a selected slot,
a drive means arranged to propel a shim tray along the channel; and
a connector arranged to detachably link the drive means to a shim tray;
wherein the connector comprises an attaching tool for attaching a shim tray to said magnet for receiving a retaining means; and
wherein the attaching tool comprises, a hollow body carrying an engagement means for engaging a complimentary feature on a shim tray; and
a concentric attachment tool substantially located within the hollow body, arranged to engage and operate an attachment means located on the shim tray.

21. The withdrawal tool according to claim 20, wherein:
said magnet includes which corresponds to said shim tray slots, for receiving a retaining means;
the retaining means is a screw; and
the attachment is a screw driver.

22. A tool according to claim 21, wherein the engagement means and the complementary feature together comprise a bayonet mechanism.

23. A method of shimming a magnet comprising:
inserting a shim tray into said magnet; and
removing the shim tray; wherein,
said step of inserting the shim tray comprises,
providing a channel having a proximal end located adjacent to the magnet and a distal end for receiving and delivering shim trays;
aligning the proximal end with a shim tray slot in a magnet;
placing a shim tray in the channel at the distal end;
connecting the shim tray to a drive means;
propelling a shim tray along the channel and into a shim tray slot using the drive means; and
said step of removing the shim tray comprises,
aligning the proximal end of the channel with the shim tray in the shim tray slot;
said drive means propelling the shim tray along the channel to the distal end of the channel; and
removing the shim tray from the channel at the distal end of the channel.

24. A method of shimming a magnet having a plurality of shim tray pockets arranged in a circular formation around the magnet, said method comprising:
mounting a rotary indexing means onto the magnet;
mounting the proximal end of the channel onto the rotary indexing means;
aligning the proximal end of the channel with a first shim tray slot, using the rotary indexing means;
inserting a shim tray into the first shim tray slot;
for each of second and remaining shim tray slots in turn,
aligning the proximal end of the channel with each of the shim tray slot, using the rotary indexing means; and
inserting a shim tray;
plotting a magnetic field generated by the magnet;
aligning the proximal end of the channel with a first shim tray slot, using the rotary indexing means;
removing the corresponding shim tray from the first shim tray slot;
and for each of second and remaining shim tray slots in turn,
aligning the proximal end of the channel with each of the shim tray slot, using the rotary indexing means;
and removing the respective shim tray;
said step of removing the shim tray comprises,
aligning the proximal end of the channel with the shim tray in the shim tray slot;
said drive means propelling the shim tray along the channel to the distal end of the channel; and
removing the shim tray from the channel at the distal end of the channel.
